(19) United States
(12) Patent Application Publication
(10) Pub. No.: US 2008/0224203 A1
(43) Pub. Date: Sep. 18, 2008

(54) SEMICONDUCTOR DEVICE HAVING ISLAND REGION

(76) Inventors: Jin-Sung Kim, Suwom-si (KR); Sung-Bae Park, Seongnam-si (KR)

Correspondence Address: F. CHAU & ASSOCIATES, LLC, 130 WOODBURY ROAD, WOODBURY, NY, 11797, US

(21) Appl. No.: 12/049,612

(22) Filed: Mar. 17, 2008

(30) Foreign Application Priority Data
Mar. 16, 2007 (KR) 10-2007-0026257

(51) Int. Cl. H01L 29/78

(52) U.S. Cl. 257/327; 257/E29.255

(57) ABSTRACT

A semiconductor device includes a semiconductor substrate which includes an active region defined by an isolation film, and a source region and a drain region defined in the active region and spaced apart from each other in the active region. The source region and the drain region each have a first conductivity type. The semiconductor device further includes an island region defined in the active region between the source region and the drain region. The island region has the first conductivity type.

### CROSS-REFERENCE TO RELATED PATENT APPLICATION

This application claims priority from Korean Patent Application No. 10-2007-0026257, filed on Mar. 16, 2007, the disclosure of which is hereby incorporated by reference herein in its entirety.

### BACKGROUND OF THE INVENTION

1. Technical Field

The present disclosure relates to a semiconductor device, and more particularly, to a semiconductor device having a metal-oxide-semiconductor field-effect transistor (MOSFET) structure.

2. Description of the Related Art

As semiconductor devices are becoming increasingly highly integrated, there is a need for semiconductor devices which have low operational power, as well as high performance. This need for semiconductor devices having low operational power, as well as high performance should increase, for example, with the increasing demand for mobile devices and the development of a system on chip (SoC) technique. Moreover, as semiconductor devices are becoming increasingly highly integrated, the critical dimension and the operational voltage of the semiconductor devices may also decrease, which in turn in may increase leakage current. As a result, it may be difficult to lower the entire operational power since lowering the operational voltage is limited. Furthermore, current conventional processing techniques may restrict the reduction in the critical dimension of the semiconductor devices.

Additionally, changing the structure and the material of semiconductor devices has been attempted to achieve high performance and low operational power. For example, a semiconductor device having a fin-FET structure and a semiconductor device employing a silicon on insulator (SOI) wafer or a high-k dielectric material have been used. However, changing the structure and the material of the semiconductor device may not only increase manufacturing costs, but also may yield unexpected side effects. Accordingly, it may be difficult to obtain highly reliable semiconductor devices and to commercially use such semiconductor devices.

### SUMMARY OF THE INVENTION

Exemplary embodiments of the present invention may provide a semiconductor device having lower operational power and high performance.

In accordance with an exemplary embodiment of the present invention, a semiconductor device is provided. The semiconductor device includes a semiconductor substrate including an active region defined by an isolation film, and a source region and a drain region defined in the active region and spaced apart from each other in the active region. The source region and the drain region each having a first conductivity type. The semiconductor device further includes an island region defined in the active region between the source region and the drain region. The island region has the first conductivity type.

In accordance with an exemplary embodiment of the present invention, a semiconductor device is provided. The semiconductor device includes a semiconductor substrate including an active region defined by an isolation film, a source region and a drain region defined in the active region and spaced apart from each other in the active region. The source region and the drain region each having a first conductivity type. The semiconductor device further includes a gate electrode formed on the semiconductor substrate to cover the active region between the source region and the drain region and an island region defined in the active region between the source region and the drain region. The island region has the first conductivity type.

In some exemplary embodiments, the island region may be spaced apart from the source and drain regions.

In some exemplary embodiments, the island region may be spaced apart from a top surface of the semiconductor substrate.

In some exemplary embodiment, the distance from the top surface of the semiconductor substrate to the upper surface of the island region may be less than the depth of the source region and the drain region in the active region.

In some exemplary embodiments, the island region may be contiguous to the top surface of the semiconductor substrate.

### BRIEF DESCRIPTION OF THE DRAWINGS

Exemplary embodiments of the present invention can be understood in more detail from the following description taken in conjunction with r the attached drawings in which:

FIG. 1 is a cross-sectional view of a semiconductor device according to an exemplary embodiment of the present invention; and

FIG. 2 is a cross-sectional view of a semiconductor device according to an exemplary embodiment of the present invention.

### DETAILED DESCRIPTION OF THE EXEMPLARY EMBODIMENTS

The present invention will now be described more fully hereinafter with reference to the accompanying drawings, in which exemplary embodiments of the invention are shown. This invention may, however, be embodied in different forms and should not be construed as limited to the embodiments set forth herein. In the drawings, the thickness of layers and regions are exaggerated for clarity.

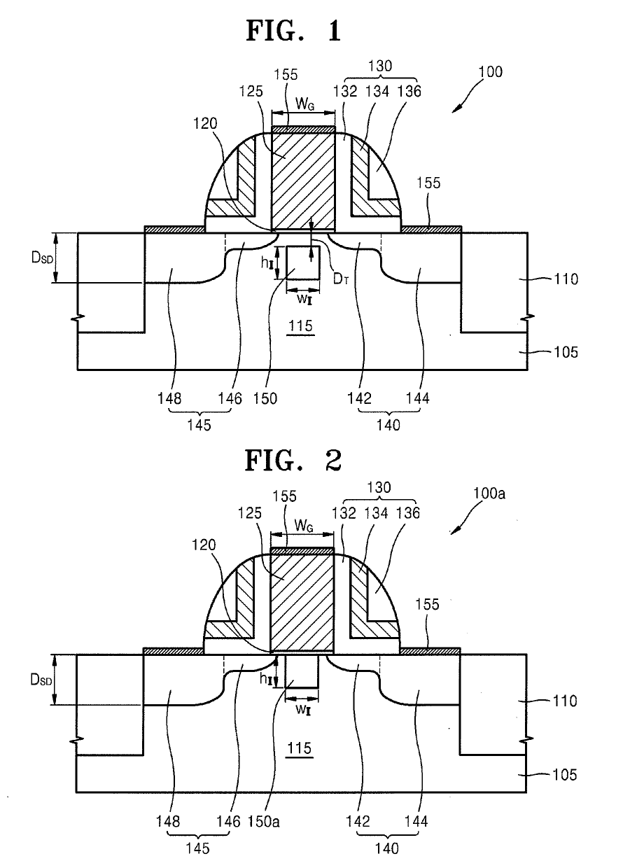

FIG. 1 is a cross-sectional view of a semiconductor device 100 according to an exemplary embodiment of the present invention. For example, the semiconductor device 100 may have a metal-oxide-semiconductor field-effect transistor (MOSFET) structure.

Referring to FIG. 1, a semiconductor substrate 105 may comprise an active region 115 defined by an isolation film 110. For example, the active region 115 may be defined as a portion of the semiconductor substrate 105 surrounded by sidewalls of the isolation film 110 that may, for example, be formed by burying an insulating material (e.g., an oxide layer and/or a nitride layer) in the semiconductor substrate 105 that may include, for example, a silicon, germanium or silicon-germanium wafer.

A source region 140 and a drain region 145 may be defined in the active region 115 and spaced apart from each other in the active region 115. For example, the source region 140 and the drain region 145 may be formed by doping the active region 115 with impurities. The source region 140 and the drain region 145 may form a diode junction with the active region 115. For example, the source region 140 and the drain region 145 may have a first conductivity type, and the active region 115 may have a second conductivity type that is opposite to the first conductivity type.

For example, if the semiconductor device 100 is an n-channel metal oxide semiconductor field effect transistor (NMOSFET), the active region 115 may be a p type region, and the source and drain regions 140 and 145 may be an n type region. When the semiconductor device 100 is a p-channel metal oxide semiconductor field effect transistor (PMOSFET), the active region 115 may be an n type region and the source and drain regions 140 and 145 may be a p type region.

The source region 140 may include a first low concentration region 142 having a first impurity concentration and a first high concentration region 144 having a second impurity concentration. The drain region 145 may include a second low concentration region 146 having the first impurity concentration and a second high concentration region 148 having the second impurity concentration. The second impurity concentration may be higher than the first impurity concentration, and the first and second low concentration regions 142 and 146 may be called a lightly doped drain (LDD) region.

A gate electrode 125 may be formed on the semiconductor substrate 105 to cover the active region 115 between the source region 140 and the drain region 145. The first and second low concentration regions 142 and 146 may partially extend below the gate electrode 125 to overlap with the gate electrode 125. A gate insulating layer 120 may be interposed between the gate electrode 125 and the semiconductor substrate 105. For example, the gate insulating layer 120 may include an oxide layer, a nitride layer, or a high-k dielectric material layer, and the gate electrode 125 may include polysilicon or metal.

An island region 150 may be defined in the active region 115 between the source region 140 and the drain region 145, and the island region 150 may have the first conductivity type. For example, the island region 150 may have a third impurity concentration that is higher than the first impurity concentration. Accordingly, if the semiconductor device 100 is an NMOSFET, the island region 150 may be an n type region. If the semiconductor device 100 is a PMOSFET, the island region 150 may be a p type region. Also, the island region 150 may be formed by heavily doping the active region 115 with impurities of the first conductivity type.

Spacer insulating layers 130 may be formed on both sidewalls of the gate electrode 125. For example, each spacer insulating layer 130 may include a structure in which a first insulating layer 132, a second insulating layer 134, and a third insulating layer 136 are stacked. For example, the first insulating layer 132 and the third insulating layer 136 may include an oxide layer, and the second insulating layer 134 may include a nitride layer. The structure and material of the spacer insulating layers 130 may be changed accordingly by one skilled in the art.

A metal silicide layer 155 may be provided on the source region 140, the drain region 145, and the gate electrode 125. For example, the metal silicide layer 155 may be formed in a self-aligned structure by reacting the materials of the source region 140, the drain region 145, and the gate electrode 125 with a metal.

In the semiconductor device 100, the island region 150 may serve as a stepping stone between the source region 140 and the drain region 145, and the island region 150 may contribute to a reduction in an effective length and volume of a channel region that forms a channel for connecting the source region 140 with the drain region 145 when the semiconductor device 100 is turned on. The channel region may be defined as a portion of the active region 115 below the gate electrode 125, and the formation of the channel needs the inversion of the channel region, rather than the inversion of the island region 150.

In this regard, the semiconductor device 100 may differ from a conventional depletion mode MOSFET where a channel region functions as a resistor and accordingly is normally turned on. However, the semiconductor device 100 is normally turned off as the semiconductor device 100 still includes the channel region.

The semiconductor device 100 can have a lower threshold voltage (e.g., a turn-on voltage) than a conventional semiconductor device that does not have the island region 150. Also, the semiconductor device 100 can have a higher saturation current (or operational current) than a conventional semiconductor device that does not have the island region 150. Accordingly, the semiconductor device 100 is applicable to low power and high performance devices.

Substantially similar effects are obtained by a decreased width W_{G} (which is also called a gate length) of the gate electrode 125. In general, a short channel below submicron dimensions may lead to a lowered threshold voltage and an increased saturation current. However, in the semiconductor device 100, the threshold voltage can be lowered and the operational current can increase without a substantial reduction in the width W_{G} of the gate electrode 125.

To reduce the effective volume of the inversion region, the island region 150 may be contiguous to the channel region, and the gate electrode 125 may be disposed to cover at least a portion of the island region 150. For example, the island region 150 may have a width W_{I} that is less than the width W_{G} of the gate electrode 125, and may be disposed between the first and second low concentration regions 142 and 146. In this case, the gate electrode 125 may cover the entire island region 150.

The distance D_{T} from a top surface of the semiconductor substrate 105 to an upper surface of the island region 150 may be less than the depth D_{SD} of the source region 140 and the drain region 145. The depth D_{SD} of the source region 140 and the drain region 145 may be an average one, and in general, the depth D_{SD} refers to the depth of the first and second high concentration regions 144 and 148. Thus, the island region 150 may be disposed close to the channel region. The height h_{I} of the island region 150 is not particularly limited in the active region 115.

The island region 150 may increase the leakage current of the semiconductor device 100, and this leakage current, however, may be controlled by a body bias voltage. For example, the off current in a standby state can be effectively reduced by applying the body bias voltage to the active region 115.

FIG. 2 is a cross-sectional view of a semiconductor device 100a according to another exemplary embodiment of the present invention. The semiconductor device 100a according to the present exemplary embodiment is substantially the same as the semiconductor device 100 of FIG. 1 except for the island region 150. Accordingly, a detailed description will be omitted.

Referring to FIG. 2, an island region 150a may be disposed to be contiguous to a top surface of the semiconductor substrate 105. That is, the island region 150a may divide the channel region into two regions. Accordingly, the semiconductor device 100a can have a lower threshold voltage and a higher operational current than the semiconductor device 100.

According to exemplary embodiments of the present invention, as an island region is disposed in an active region, a semiconductor device can have a lower threshold voltage and a higher operational current that allows the semiconductor device to be applicable to low power and high performance devices.

Furthermore, with semiconductor devices according to exemplary embodiments of the present invention, leakage current can be reduced through an adjustment of the body bias voltage.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A semiconductor device comprising:
a semiconductor substrate including an active region defined by an isolation film;
a source region and a drain region defined in the active region and spaced apart from each other in the active region, the source region and the drain region each having a first conductivity type; and
an island region defined in the active region between the source region and the drain region, and the island region having the first conductivity type.

2. The device of claim 1, wherein the island region is spaced apart from the source region and the drain region.

3. The device of claim 1, wherein the island region is spaced apart from a top surface of the semiconductor substrate.

4. The device of claim 3, wherein a distance from the top surface of the semiconductor substrate to an upper surface of the island region is less than a depth of the source region and the drain region in the active region.

5. The device of claim 1, wherein the island region is contiguous to the top surface of the semiconductor substrate.

6. The device of claim 1, wherein each of the source region and the drain region comprises a low concentration region having a first impurity concentration and a high concentration region having a second impurity concentration higher than the first impurity concentration.

7. The device of claim 6, wherein the island region is disposed between the low concentration region of the source region and the low concentration region of the drain region.

8. The device of claim 6, wherein the island region has a third impurity concentration that is higher than the first impurity concentration.

9. The device of claim 1, further comprising a gate electrode formed on the semiconductor substrate to cover the active region between the source region and the drain region, the gate electrode covering at least a portion of the island region.

10. The device of claim 9, wherein the gate electrode covers the entire island region.

11. The device of claim 9, wherein the island region has a smaller width than the gate electrode.

12. A semiconductor device comprising:
a semiconductor substrate including an active region defined by an isolation film;
a source region and a drain region defined in the active region and spaced apart from each other in the active region, the source region and the drain region each having a first conductivity type;
a gate electrode formed on the semiconductor substrate to cover the active region between the source region and the drain region; and
an island region defined in the active region between the source region and the drain region, and the island region having the first conductivity type.

13. The device of claim 12, wherein the island region is spaced apart from the source region and the drain region.

14. The device of claim 12, wherein the island region is spaced in the active region from a top surface of the semiconductor substrate.

15. The device of claim 14, wherein a distance from the top surface of the semiconductor substrate to an upper surface of the island region is less than a depth of the source region and the drain region in the active region.

16. The device of claim 12, wherein the island region is contiguous to the top surface of the semiconductor substrate.

17. The device of claim 12, wherein the gate electrode covers at least a portion of the island region.
